(19) United States
(12) Patent Application Publication
(10) Pub. No.: US 2003/0162131 A1
(43) Pub. Date: Aug. 28, 2003

(54) Laser recording method for imaging materials coated on-site

(76) Inventors: Bradley J.F. Palmer, Surrey (CA); Lauren Walker, North Vancouver (CA)

Correspondence Address: David J. McGruder, Oyen Wiggs Green & Mutala, #480, 601 West Cordova Street, Vancouver, BC, V6B 1G1, CA

(21) Appl. No.: 10/373,849

(22) Filed: Feb. 27, 2003

Related U.S. Application Data
(60) Provisional application No. 60/359,703, filed on Feb. 27, 2002.

(51) Int. Cl. G03F 7/00; G03F 7/26; G03B 27/52; B41N 3/00; B41M 5/00

(52) U.S. Cl. 430/302; 355/55; 101/463.1

(57) ABSTRACT

A method for the on-site creation of a lithographic printing surface by imagewise illuminating an imaging element based on thermally imageable material, which is itself applied and prepared on-site, with a shaped laser recording spot. The shaped laser recording spot has an energy profile with a very sharp transition between the writing and non-writing area in both dimensions, and is created by a shaping the laser energy into a line narrower than the desired spot size and scanning this line to create a square spot. The sharp transition is less sensitive to variation in exposure characteristics of the imaging element. The imaging element is prepared on-site by coating an imageable material onto a lithographic surface and performing all the steps of curing, imaging and development on the press and/or in an off-press platemaking device. Subsequent cleaning of the printing surface, in order to reuse the lithographic base, may also be performed on the same equipment. The lithographic surface can be a printing plate lithographic base, the printing cylinder of a printing press, or a sleeve mounted around the printing cylinder of a printing press. This cylinder can be conventional or seamless. The lithographic printing surface may be used for printing long run lengths on lower quality paper and in the presence of pressroom chemicals.

### CROSS-REFERENCE TO RELATED APPLICATION

This application claims the benefit of the filing date of provisional application No. 60/359,703, filed Feb. 27, 2002.

### FIELD OF THE INVENTION

The invention pertains to the field of lithography and in particular to imaging materials and methods for imaging printing materials coated at the printing site.

### BACKGROUND OF THE INVENTION

Lithographic printing presses use a printing master such as a printing plate that is mounted on a cylinder of the printing press. The master carries a lithographic image on its surface and a print is obtained by applying ink to said image and then transferring the ink from the master onto a receiver material, which typically is paper. In conventional lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. In so-called driographic printing, the lithographic image consists of ink-accepting and ink-adhesive areas and during this kind of printing, only ink is supplied to the master.

Printing masters have traditionally been obtained by the computer-to-film method, wherein various pre-press steps such as typeface selection, scanning, color separation, screening, trapping, layout and imposition are accomplished digitally and each color selection is transferred to graphic arts film using an image-setter. After processing, the film can be used as a mask for the exposure of an imaging material on a plate, also known as a plate precursor. After the plate precursor has been processed, a printing plate is obtained which can be used as a master.

More recently the computer-to-plate (CTP) method has gained a lot of interest. This method, also called direct-to-plate method, bypasses the creation of film because the digital document is transferred directly to a lithographic printing precursor by means of a plate-setter machine. In the field of such computer-to-plate methods the following improvements are at present being studied:

(i) On-Press Imaging.

A special type of a computer-to-plate process involves the exposure of a lithographic printing precursor while it is mounted on a plate cylinder of a printing press. This is done by means of an image-setter that is integrated in the press. This method may be called ‘computer-to-press’ and printing presses with an integrated plate-setter are sometimes called digital presses. A review of digital presses is given in the Proceedings of the Imaging Science & Technology's 1997 International Conference on Digital Printing Technologies (Non-Impact Printing 13). Computer-to-press methods have been widely described and are well known to those schooled in the art of commercial printing. Typical printing precursor materials used in computer-to-press methods are based on ablation. A problem associated with ablative precursors, is the generation of debris, which is difficult to remove and may disturb the printing process or may contaminate the exposure optics of the integrated image-setter. Other methods require wet processing with chemicals. Such processes may damage or contaminate the electronics and optics of the integrated image-setter and other devices of the press.

(ii) On-Press Coating.

Whereas a printing precursor normally consists of a sheet-like support and one or more functional coatings, computer-to-press methods have been described wherein a composition, capable of forming a lithographic surface upon image-wise exposure and optional processing, is provided directly on the surface of a plate cylinder of the press. Techniques have also been described in which a coating of a hydrophobic layer is applied directly on the hydrophilic surface of a plate cylinder. After removal of the non-printing areas by ablation, a master is obtained. However, ablation should be avoided in computer-to-press methods, as discussed above. In U.S. Pat. No. 5,713,287 a computer-to-press method is described wherein an imageable medium is applied directly on the surface of a plate cylinder. The imageable medium is converted from a first water-sensitive or oil-sensitive property to an opposite water-sensitive or oil-sensitive property by image-wise exposure.

(iii) Thermal Imaging.

Most of the computer-to-press methods referred to above use so-called thermal or heat-mode materials, i.e. printing precursors or on-press coatable compositions, which comprise a compound that converts absorbed light into heat. The heat which is generated on image-wise exposure triggers a (physico-) chemical process, such as ablation, polymerization, insolubilization by cross-linking of a polymer, decomposition, or particle coagulation of a thermoplastic polymer latex, and after optional processing, a lithographic image is obtained.

(iv) The Development of Special Delivery Functional Coatings

Another major trend in plate-making is special functional coatings. Examples of such coatings include ones that require no wet processing, or that may be processed with plain water, ink or fountain solution. Such materials are especially desirable in computer-to-press methods so as to avoid damage or contamination of the optics and electronics of the integrated image-setter by contact with the processing liquids. Most such printing precursors are, however, ablative, and have a multi-layer structure that makes them less suitable for on-press coating. However, non-ablative printing precursors that can be processed with plain water have been described. Such printing precursors also allow on-press processing, either by wiping the exposed printing precursor with water while it is mounted on the press, or by the ink or fountain solution applied during the first runs of the printing job.

(v) On-Site Coating of Printing Precursors

Preparation of printing masters by coating and imaging on-press was mentioned above in section (ii) as was reusing the master lithographic base by means of removing or cleaning the printing surface from the lithographic base. Coating of printing precursor masters off press has existed since the 1960's as hand-wiped plates using visible light sensitive media. This process, due to poor coating quality associated with hand coating, has fallen out of favour given increased demand for quality printing and has in general been replaced by precoated thermal plates. In the case of hand-coated plates, however, the lithographic bases were not reused. There is value in reusing the lithographic base as the materials and production of such lithographic base can be costly. This is becomes even more feasible for shorter print runs where the mechanical properties of the lithographic base do not degrade significantly. There is thus interest in the process of reusing lithographic bases by removing printing master from the press, and installing it in a separate device whereby the printing surface is removed, the base is recoated, and optionally imaged for reuse in printing.

A computer-to-press method has also been disclosed in which an oleophilic substance is image-wise transferred from a foil to a rotary press cylinder by melting said substance locally with a laser beam. The strip-shaped transfer foil has a narrow width compared to the cylinder and is translated along a path which is parallel to the axis of the cylinder while being held in close contact with the surface of the cylinder so as to build up a complete image on that surface gradually. As a result, this system is rather slow and requires a long downtime of the printing press, thereby reducing its productivity.

An on-press coating method has been described wherein an aqueous liquid, comprising a hydrophilic binder, a compound capable of converting light to heat and hydrophobic thermoplastic polymer particles, is coated on the plate cylinder so as to form a uniform, continuous layer thereon. Upon image-wise exposure, areas of the coated layer are converted into a hydrophobic phase, thereby defining the printing areas of the printing master. The press run can be started immediately after exposure without any additional treatment because the layer is processed by interaction with the fountain and ink that are supplied to the cylinder during the press run. So the wet chemical processing of these materials is ‘hidden’ to the user and accomplished during the first runs of the printing press. After the press run, the coating can be removed from the plate cylinder by an on-press cleaning step. Such methods of on-press coating, on-press exposure and on-press cleaning of the master are commercially attractive because, contrary to conventional lithographic printing, they can be carried out without specialized training or experience. Such presses require less human intervention than conventional presses.

As may be seen from the foregoing, the technology of on-press imaging and on-site platemaking has made major strides and represents a major benefit to industry. However, a problem associated with coating lithographic base materials, both on-press and in dedicated off-press coating and imaging equipment, is that the method produces an insufficient coating quality, characterized by a low consistency and a high frequency of coating artifacts.

As described by Gelbart in U.S. Pat. No. 6,266,080, the rate of exposure is crucial when imaging thermal, or heat-mode, materials. The optical properties of such materials determine the rate at which thermal energy is absorbed and hence how the image is created. The optical properties are governed by such parameters as the lithographic base material and surface properties, the composition and thickness of the thermal coating, and the surface finish of the thermal coating. When thermal media are manufactured off-site, on large-scale coating equipment, these parameters are tightly controlled such that the imaging properties of the thermal media are kept very constant. In on-site coating technologies, such tight control of parameters is not achievable due to effects such as changes in the lithographic base surface resulting from repeated cleaning as well as variations in coating thickness and surface texture due to the application process. As a result, thermal media coated on-site or on-press inherently has less consistent exposure characteristics. This can be even more crucial when on-site coating and lithographic base reuse are conducted directly on the printing press, because the normal plate cylinder temperature can vary drastically (e.g. 5 to 60 degrees Celsius depending on whether the press is cold or hot) resulting in a variable contribution to the thermal reaction process. Processing conditions on-press are also quite variable due to, for example, different fountain solutions, press roller type and number, different inks and press condition. These complexities of on-site platemaking lead to inconsistencies in the printing performed with the resulting lithographic printing surface due to, for instance, poor durability, variable dot gain, and tone shifts as the printing surface is subject to wear.

It is an objective of the present invention to provide a recording method with which consistent printing performance can be obtained with a printing surface that has been created by coating an imageable material onto a lithographic surface and subsequently imaged while the lithographic surface is mounted on a press or in an off-press platemaking device. Said consistent printing performance may be achieved, for instance, by resulting improvements in durability, variable dot gain, and tone shifts as the printing surface is subject to wear. This will make possible the commercial application of the fully integrated on-press coating, imaging and printing process in addition to the reuse of lithographic bases both on and off press.

### BRIEF SUMMARY OF THE INVENTION

A method is provided for the on-site creation of a lithographic printing surface by imagewise illuminating an imaging element based on thermally imageable material, which is itself applied and prepared on-site, with a shaped laser recording spot. The shaped laser recording spot has an energy profile with a very sharp transition between the writing and non-writing area in both dimensions, and is created by shaping the laser energy into a line narrower than the desired spot size and scanning this line to create a square spot. The sharp transition is less sensitive to variation in exposure characteristics of the imaging element. The imaging element is prepared on-site by coating an imageable material onto a lithographic surface and performing all the steps of curing, imaging and development on the press and/or in an off-press platemaking device. Subsequent cleaning of the printing surface, in order to reuse the lithographic base, may also be performed on the same equipment. The lithographic surface can be a printing plate lithographic base, the printing cylinder of a printing press, or a sleeve mounted around the printing cylinder of a printing press. This cylinder can be conventional or seamless. The lithographic printing surface may be used for printing long run lengths on lower quality paper and in the presence of pressroom chemicals.

The invention also provides an apparatus for creating a lithographic printing surface. A light source, preferably a laser, is provided for radiating a surface of a thermally convertible lithographic printing precursor on a press. An apparatus, such as a linear light source or other optical system, is used to provide a narrow, substantially continuous line of radiation impinging on the precursor surface. An apparatus creates relative motion between the thermally convertible lithographic printing precursor and the line of radiation.

### BRIEF DESCRIPTION OF THE DRAWINGS

FIG. 1a shows the scanning employed by prior art imaging systems.

FIG. 1b shows the energy profile of the scanning spots of prior art systems.

FIG. 2a shows the scanning employed in the present invention.

FIG. 2b shows the energy profile of a mark produced using the method of the present invention.

FIG. 3 shows an embodiment of the present invention wherein the light source is directly imaged on a medium to be marked.

FIG. 4 shows an embodiment of the present invention wherein the far-field pattern of the light source is imaged on the medium to be marked.

FIG. 5 shows an embodiment of the present invention wherein an optical fiber is used to shape the light from the light source.

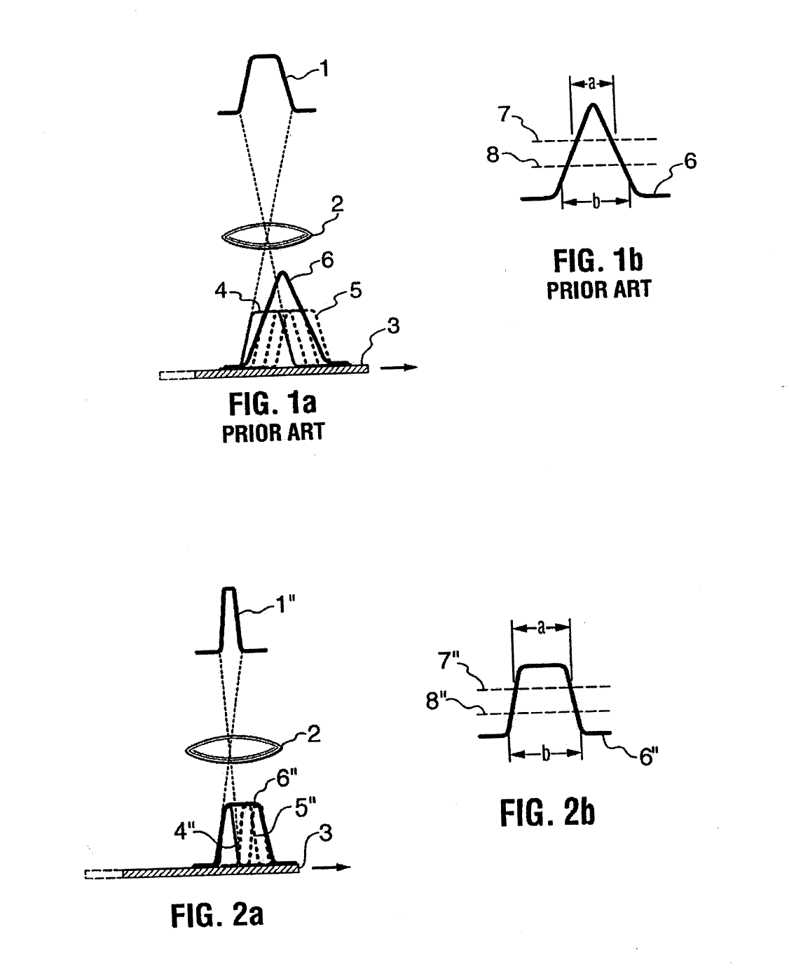

### DETAILED DESCRIPTION OF THE PREFERRED EMBODIMENT

The preferred embodiment of the present invention is a method for the on-press creation of a lithographic printing surface by imagewise illuminating with a shaped laser recording spot a thermally convertible lithographic printing precursor which is prepared on-press. By virtue of the practicalities of on-press coating of imageable materials, the properties of the as-coated thermally convertible lithographic printing precursor may vary substantially over its surface. The shape of the laser recording spot may be square, rectangular or parallelogram-shaped. It may have an energy profile with a very sharp transition between the writing and on-writing area in both dimensions. The laser energy is shaped into a line narrower than the desired spot size and the line is scanned to create a shaped spot. U.S. Pat. No. 6,121,996 (Gelbart) describes a process for ensuring a shaped laser spot for creating printing dots on a lithographic printing surface and he specification of that patent is hereby fully incorporated by reference.

The present invention permits the use of a laser to generate a mark having sharp transitions at all of its edges, even when relative motion exists between the laser recording spot and the thermally convertible lithographic printing precursor being marked for the duration of the marking. In general, the mark is the smallest picture element, also known as “pixel” or “pel”. The laser recording spot is shaped into a line having a cross section shown by shape 1″ of FIG. 2a. The term “laser recording spot” is used herein to describe the laser spot as produced by the laser without any scanning of either the laser beam or the thermally convertible lithographic printing precursor.

FIG. 2a is a cross-section through thermally convertible lithographic printing precursor 3 being marked according to the invention taken in the direction of the relative motion between the laser scanning spot and thermally convertible lithographic printing precursor 3. The width of shape 1″ has to be less than the length of the desired mark in the direction of the relative motion. Typically, the width of shape 1″ should be from 10% to 50% of the width of the desired mark. The laser line is imaged by lens 2 onto thermally convertible lithographic printing precursor 3.

As the image of the laser line is scanned across thermally convertible lithographic printing precursor 3 (by the relative motion) the image moves from position 5″ to position 4″ during the duration of writing the mark. The sum of the exposure generates energy profile 6″. If width of shape 1″ were zero, the shape of energy profile 6″ would be perfectly square. Because of physical limits, shape 1″ has a finite width, which determines the transition time (also know as “optical rise time”) of profile 6″. For a line having a cross-sectional shape 1″ with a width significantly less than the width of the desired profile 6″, an exposure function immune to process changes is created. This is shown in FIG. 2b. When the threshold at which thermally convertible lithographic printing precursor 3 becomes marked changes from an energy density indicated by line 7″ to a lower energy density indicated by line 8″, the size of the mark changes from “a” to “b”. This change is much less than in prior art methods and allows superior control of the imaging process.

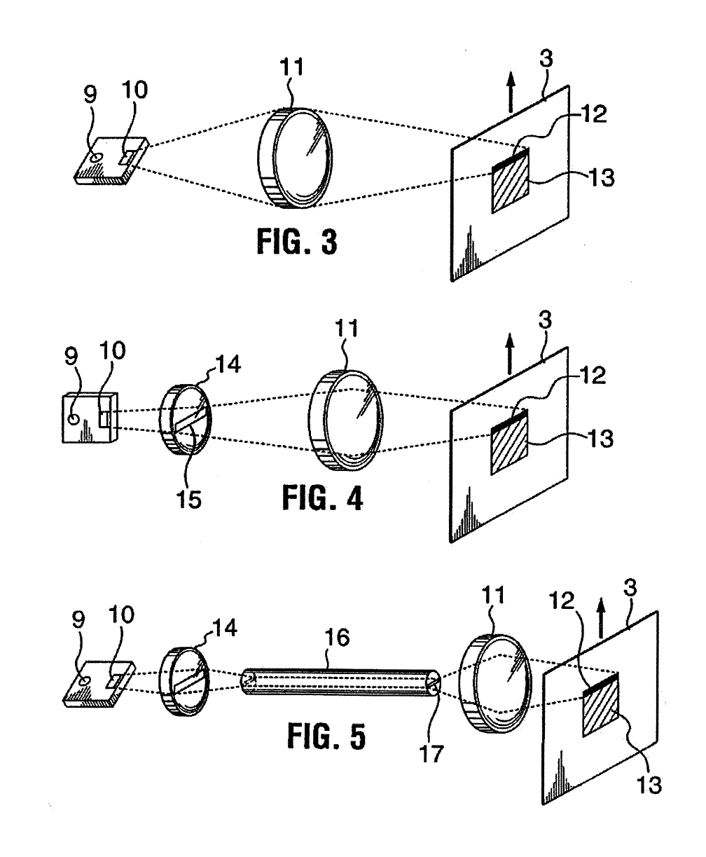

The present invention can be implemented in many different ways. Three of them are shown in FIG. 3, FIG. 4 and FIG. 5. In FIG. 3 a narrow line is generated by directly imaging a linear light source onto the recorded material. The linear light source can be the emitter (facet) 10 of multi-mode laser diode 9, imaged into line 12 by lens 11. Scanning line 12 for the duration of one pixel on thermally convertible lithographic printing precursor 3 creates a square spot 13 with a sharp transition in the energy profile on all four sides. Clearly any linear light source such as a linear light bulb or a linear light valve can be substituted for laser diode 9. The term “light source” is used herein to describe any source of light that may be used to image thermally convertible lithographic printing precursor 3 combined with any additional optical subsystems, including any form of light valve, spatial light modulator or deformable mirror device, required to produce a linearly shaped source of light.

One disadvantage of this method is that any non-uniformity in emitter 10 will be reproduced in line 12. A different method, with more immunity to non-uniformity of the laser emitter is shown in FIG. 4. Instead of imaging the emitter 10 directly, the far field pattern 15 of the emitter, as formed on collection lens 14, is imaged into line 12.

A third way of generating a line image is shown in FIG. 5. Laser diode 9 is coupled into optical fiber 16 using conventional means such as a lens 14. Fiber 16 has a rectangular core 17. The illuminated end of core 17 is imaged by a lens 11 onto material 3 to form line 12 and square spot 13. The advantage of this method is high degree immunity to non-uniformity in the radiation pattern of laser 9. A further advantage is the higher coupling efficiency achieved when coupling a rectangular emitter into a rectangular fiber core, compared to prior art of coupling a rectangular emitter into a round core. Rectangular core fibers are manufactured by the same process as round core fibers, by starting with a preform having a rectangular core. While laser 9 in FIGS. 3-5 can be at any wavelength, the invention is particularly useful in thermal recording using near IR lasers.

The phrase “lithographic printing precursor” is used herein to describe any printing plate, printing cylinder, printing cylinder sleeve, or any other surface bearing a coating of imageable material that may be either converted or removed imagewise to create a surface that may be inked selectively and used for lithographic printing. The phrase “lithographic printing surface” is used herein to describe the selectively inkable surface so created. The term “imageable material” is used to describe a material capable of having rendered within it or on its surface an imagewise distributed change in response to being imagewise illuminated or irradiated in the corresponding areas.

The phrase “thermally convertible lithographic printing precursor” is used herein to describe a lithographic printing precursor in which the converting or removing is performed by means of heat. Examples of such precursors include media that change their hydrophilicity and/or oleophilicity upon exposure to heat, herein referred to as “thermal surface change media”, media that are ablated by heat, herein referred to as “thermally ablative media” and media that are imageable by heat and developable using various developers including aqueous developers such as fountain solution, herein referred to as “developable thermal media”.

Any of the thermally convertible lithographic printing precursors has a number of different thermal exposure properties. The term “thermal exposure property” is used herein to describe any property that affects the degree of response in the form of change, conversion or ablation induced in the precursor by a given amount of thermal energy transferred to or generated in the precursor by the laser radiation in spot. Thermal exposure properties include thickness of the imageable material, roughness of the surface of the imageable material, roughness of the surface of lithographic base onto which the imageable material is coated, composition of the imageable material, age of the imageable material after preparation, reflectivity of the imageable material and absorption properties of the imageable material as well as its inherent sensitivity to the radiation employed by the laser. All of these factors may vary across the surface of the coated thermally convertible lithographic printing precursor and cause the response of the precursor to vary.

In the preferred embodiment of the invention, the thermally convertible lithographic printing precursor is prepared on-press by coating a thermally imageable medium onto a hydrophilic surface and performing all the steps of curing, imaging and development on the press. Before applying the imageable coating to the lithographic base, the lithographic base may be treated to enhance the developability or adhesion of the imageable coating. After use, the imageable material may be cleaned from the lithographic base for another run. This cleaning step may also be performed on-press. These various process steps of the present invention are as described by Gelbart in U.S. Pat. No. 5,713,287, which is hereby incorporated in full by reference.

The hydrophilic surface can be a printing plate lithographic base, the printing cylinder of a printing press, or a sleeve around the printing cylinder of a printing press. This cylinder can be conventional or seamless. The sharp transition in the energy profile of the square shaped laser recording spot is less sensitive to variation in exposure characteristics of the imaging element resulting from on-site coating of imageable material in addition to the reuse of lithographic bases. The lithographic base may be an integral part of the press or it may be removably mounted on the press. The specific term “lithographic base” is used herein to describe the base onto which the imageable material is coated. Some imageable materials may require curing before imaging. The imageable material coating may be cured by means of a curing unit integral with the press, as described by Gelbart in U.S. Pat. No. 5,713,287. The term “curing” is here to be understood to include the hardening of the imageable medium, specifically including the drying thereof, either with or without cross-linking of an incorporated polymer.

The lithographic bases used in accordance with the present invention are preferably formed of aluminum, zinc, steel, or copper. These include the known bi-metal and tri-metal plates such as aluminum plates having a copper or chromium layer; copper plates having a chromium layer, and steel plates having copper or chromium layers. Other preferred lithographic bases include metallized plastic sheets such as poly(ethylene terephthalate). Any of these lithographic base materials may be pre-coated with polymeric or ceramic coatings in order to improve properties such as adhesion, durability, and resistance to corrosive attack.

Particularly preferred lithographic bases are grained, or grained and anodized, aluminum plates where the surface is roughened (grained) mechanically, chemically (e.g. electrochemically), or by a combination of roughening treatments. The anodizing treatment can be performed in an aqueous acid electrolytic solution such as sulphuric acid or a combination of acids such as sulphuric and phosphoric acid. According to the present invention, the anodized aluminum surface of the lithographic base may be treated to improve the hydrophilic properties of its surface. For example, a phosphate solution that may also contain an inorganic fluoride is applied to the surface of the anodized layer. The aluminum oxide layer may be also treated with sodium silicate solution at an elevated temperature, e.g. 90° C. Alternatively, the aluminum oxide surface may be rinsed with a citric acid or citrate solution at room temperature or at slightly elevated temperatures of about 30 to 50° C. A further treatment can be made by rinsing the aluminum oxide surface with a bicarbonate solution.

According to another embodiment in connection with the present invention, the lithographic base having a hydrophilic surface comprises a flexible support, such as paper or plastic film, provided with a cross-linked hydrophilic layer. A particularly preferred lithographic base to use is a polyester film on which an adhesion-promoting layer has been added. Suitable adhesion-promoting layers for use in accordance with the invention comprise a hydrophilic (co-) polymer and colloidal silica as disclosed in EP 619524, and EP 619525. Preferably, the amount of silica in the adhesion-promoting layer is between 0.2 and 0.7 mg per m². Further, the ratio of silica to hydrophilic binder is preferably more than 1 and the surface area of the colloidal silica is preferably at least 300 m² per gram.

In the case of developable thermal media being employed, the thermally convertible lithographic printing precursor may be subsequently developed after exposure using an appropriate developer. Again, as described by Gelbart in U.S. Pat. No. 5,713,287, this process may be conducted directly on the press.

In a further embodiment of the present invention, the entire process of creating the lithographic printing surface may be undertaken off-press on a separate plate-setter machine. This includes at least the steps of coating the imageable material onto the lithographic base and imaging the thermally convertible lithographic printing precursor so created. Some imeageable materials may require a curing step, which is then also to be conducted on the plate-setter machine before imaging. Clearly this particular embodiment does not involve on-press coating

The benefits of the method of the present invention reside in the use of the imaging by a shaped laser spot of a layer of a thermally convertible lithographic printing precursor prepared on-press or on-platesetter under press-room conditions, where conditions are by their very nature less than optimal for lithographic plate manufacture.

There have thus been outlined the important features of the invention in order that it may be better understood, and in order that the present contribution to the art may be better appreciated. Those skilled in the art will appreciate that the conception on which this disclosure is based may readily be utilized as a basis for the design of other apparatus and methods for carrying out the several purposes of the invention. It is most important, therefore, that this disclosure be regarded as including such equivalent apparatus and methods as do not depart from the spirit and scope of the invention.

What is claimed is:

1. A method for obtaining a lithographic printing surface comprising the steps of:
a. preparing a thermally convertible lithographic printing precursor, said preparing comprising coating a lithographic base with a thermally imageable medium, and
b. image-wise exposing to radiation from a laser said thermally convertible lithographic printing precursor, said imagewise exposing comprising
i. operating said laser to illuminate a surface of said thermally convertible lithographic printing precursor with a narrow, substantially continuous line of laser radiation; and
ii. creating relative motion between said thermally convertible lithographic printing precursor and said line of laser radiation in a direction substantially transverse to an orientation of said line so that said line sweeps over a region on said thermally convertible lithographic printing precursor and changes a property of said thermally imageable medium in said region.

2. A method as in claim 1, wherein said coating is performed while said lithographic base is mounted on a press.

3. A method as in claim 1, wherein said coating has a substantially uneven thermal exposure property.

4. A method as in claim 1, wherein said thermally imageable medium is selected from the group consisting of thermal surface change media, thermally ablative media and developable thermal media.

5. A method as in claim 4, wherein said developable thermal media are developable using an aqueous medium, including fountain solution.

6. A method for obtaining a lithographic printing surface as in claim 1, wherein said radiation is light.

7. A method for obtaining a lithographic printing surface as in claim 6, wherein said light is infrared.

8. A method for obtaining a lithographic printing surface as in claim 7, wherein said laser is an infrared laser.

9. The method of claim 1, wherein said region on said thermally convertible lithographic printing precursor is a rectangle.

10. The method of claim 9, wherein said region on said thermally convertible lithographic printing precursor is square.

11. The method of claim 9, wherein said line has a width which is no more than 50% of a width of said rectangle.

12. The method of claim 11 wherein said line has a width which is in the range of 10% to 50% of the width of said rectangle.

13. The method of claim 1, wherein said laser has a linear emitter and said operating comprises imaging said linear emitter onto said surface.

14. The method of claim 1, wherein said operating comprises generating a beam of laser radiation from said laser and shaping said beam to provide said narrow substantially continuous line of laser radiation impinging on said surface.

15. The method of claim 14 wherein said shaping the beam comprises passing said beam into an optical fiber having a rectangular core and imaging an illuminated rectangular end of said rectangular core on said surface.

16. The method of claim 15, wherein said laser comprises a rectangular emitter.

17. The method of claim 14 wherein said shaping the beam comprises illuminating a linear light valve with the beam and imaging said illuminated linear light valve on said surface.

18. The method of claim 14, wherein said shaping the beam comprises imaging an emitter of the laser with a lens to create a far-field pattern and imaging the far-field pattern onto said surface.

19. A method for writing a pixel having parallel first and second edges on a thermally convertible lithographic printing precursor on a press, said method comprising:
a. providing a press comprising a light source and an optical system for focusing light from said light source,
b. preparing a thermally convertible lithographic printing precursor on said press, said preparing comprising coating a lithographic base with a thermally imageable medium while said lithographic base is mounted on said press,
c. focussing said light source onto a line on the surface of said thermally convertible lithographic printing precursor, said line having a width and first and second ends substantially coincident with the first and second edges of said pixel respectively;
d. operating said light source to illuminate said line when said line is substantially coincident with a third edge of the pixel;
e. creating relative motion between said line and said thermally convertible lithographic printing precursor in a direction parallel to said first and said second edges of the pixel and thereby sweeping said line across an area of said pixel; and
f. ceasing to illuminate said line when said line is substantially coincident with a fourth edge of said pixel;
g. wherein the width of said line is no more than 50% of a distance between said third and said fourth edges of said pixel.

20. The method of claim 19 wherein, when said line is substantially coincident with said fourth edge of said pixel, said line does not substantially overlap with another pixel adjacent to said fourth edge of said pixel.

21. The method of claim 19 wherein said line is substantially perpendicular to said first and said second edges and said pixel is rectangular.

22. The method of claim 21 wherein said pixel is square.

23. A method for writing a pixel having parallel first and second edges on a thermally convertible lithographic printing precursor, said method comprising:
a. preparing a thermally convertible lithographic printing precursor on a plate-setter machine, said plate-setter machine comprising a light source and an optical system for focusing light from said light source, said preparing comprising coating a lithographic base with a thermally imageable medium having a substantially varying thermal exposure property;
b. focusing said light source onto a line on the surface of said thermally convertible lithographic printing precursor, said line having a width and first and second ends substantially coincident with the first and second edges of said pixel respectively;
c. operating said light source to illuminate said line when said line is substantially coincident with a third edge of the pixel;
d. creating relative motion between said line and said thermally convertible lithographic printing precursor in a direction parallel to said first and said second edges of the pixel and thereby sweeping said line across an area of said pixel; and
e. ceasing to illuminate said line when said line is substantially coincident with a fourth edge of said pixel;
f. wherein the width of said line is no more than 50% of a distance between said third and said fourth edges of said pixel.

24. The method of claim 23, wherein, when said line is substantially coincident with said fourth edge of said pixel, said line does not substantially overlap with another pixel adjacent to said fourth edge of said pixel.

25. The method of claim 23, wherein said line is substantially perpendicular to said first and said second edges and said pixel is rectangular.

26. The method of claim 25, wherein said pixel is square.

27. A lithographic printing surface prepared by the method of claim 1.

28. An apparatus for making a lithographic printing surface on a thermally convertible lithographic printing precursor on a press, comprising:
a. a light source for radiating a surface of said thermally convertible lithographic printing precursor;
b. an apparatus for shaping a beam of radiation from said light source to provide a narrow, substantially continuous line of radiation impinging on said surface; and
c. an apparatus for creating relative motion between said thermally convertible lithographic printing precursor and said line of radiation in a direction substantially transverse to an orientation of said line.

29. An apparatus according to claim 28 wherein said light source is a laser.

30. An apparatus according to claim 28 wherein said apparatus for shaping a beam of radiation is selected from the group consisting of a lens, a linear light valve, a special light modulator, a deformable mirror device and an optical filter having a rectangular core.
